(19) United States
(12) Patent Application Publication
(10) Pub. No.: US 2009/0236130 A1
(43) Pub. Date: Sep. 24, 2009

(54) Multilayered printed circuit board and method of manufacturing the same

(75) Inventors: Jee Soo Mok, Gyunggi-do (KR); Je Gwang Yoo, Gyunggi-do (KR); Chang Sup Ryu, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/216,428

(22) Filed: Jul. 3, 2008

(30) Foreign Application Priority Data
Mar. 18, 2008 (KR) 10-2008-0025035

(51) Int. Cl. H05K 1/09; H05K 3/42

(52) U.S. Cl. 174/257; 29/852

(57) ABSTRACT

Disclosed herein is a multilayered circuit board, including: a metal base layer including a metal layer formed through-holes, an insulating film formed on a surface of the metal layer, a first circuit layer having circuit patterns formed on one side of the metal layer and a second circuit layer having protruding connecting pads, formed on the other side of the metal layer; a build-up layer formed on the first circuit layer; and a solder resist layer. The multilayered printed circuit board is advantageous in that the thickness thereof is decreased and the bending strength and radiation characteristics thereof are improved.

### CROSS REFERENCE TO RELATED APPLICATION

This application claims the benefit of Korean Patent Application No. 10-2008-0025035, filed Mar. 18, 2008, entitled “Multilayer printed circuit board and a fabricating method of the same”, which is hereby incorporated by reference in its entirety into this application.

### BACKGROUND OF THE INVENTION

1. Field of the Invention

The present invention relates to a multilayered printed circuit board and a method of manufacturing the same, and, more particularly, to a multilayered printed circuit board which is thinner and has improved bending strength and radiation characteristics, and a method of manufacturing the same.

2. Description of the Related Art

Generally, printed circuit boards (PCBs) are manufactured by patterning one or both sides of a substrate, composed of various thermosetting resins, using copper foil, and disposing and fixing ICs or electronic parts on the substrate, thus forming electric circuits therebetween.

Recently, with the advancement of the electronics industry, electronic parts are increasingly required to be highly functionalized, and to be light, thin, short and small. Printed circuit boards loaded with such electronic parts are also required to be highly densified and thin.

In particular, since conventional build-up circuit boards are used as products in a state in which a build-up layer is formed on a core substrate, there is a problem in that the thickness of the build-up circuit board is increased. That is, when the thickness of the build-up circuit board is increased, there is also a problem in that the length of the circuit is increased, so that the signal processing time is increased, thereby preventing the circuit from being highly densified.

In order to overcome the above problems, a coreless substrate having no core is proposed. FIG. 1 shows a conventional process of manufacturing a coreless substrate. Hereinafter, the conventional process of manufacturing a coreless substrate will be described with reference to FIG. 1.

First, as shown in FIG. 1A, a metal carrier 10, used to support a coreless substrate during the process, is prepared.

Subsequently, as shown in FIG. 1B, a metal barrier 11 is formed on one surface of the metal carrier 10, and a circuit pattern 12 is formed on the metal barrier 11.

Subsequently, as shown in FIG. 1C, a build-up layer 13, including a plurality of insulation layers and a plurality of circuit layers, is formed on the circuit pattern 12. Here, the build-up layer is formed using a general build-up method.

Subsequently, as shown in FIG. 1D, the metal carrier 10 and the metal barrier are removed.

Finally, as shown in FIG. 1E, solder resist layers 14 are formed on the uppermost and lowermost layers of the build-up layer 13, respectively, thereby manufacturing a coreless substrate 15.

As such, the conventional coreless substrate 15 is manufactured by forming a build-up layer 13 through a metal carrier 10, functioning as a support, and then removing the metal carrier therefrom.

However, the conventional coreless substrate 15 is problematic in that it bends when it is put to practical use because the metal carrier 10 functions as a support during the process but is removed after the process, and in that electronic parts do not function properly and are damaged because a large amount of heat is generated when an electronic circuit is formed using the electronic parts.

Further, the conventional coreless substrate 15 is problematic in that an additional process for removing the metal carrier 10 is required, and solder resist layers 14 must be additionally formed in order to protect the circuit pattern exposed after the removal of the metal carrier 10.

### SUMMARY OF THE INVENTION

Accordingly, the present invention has been made keeping in mind the above problems occurring in the prior art, and the present invention provides a multilayered printed circuit board, which has excellent radiation performance and is prevented from being bent because it includes a metal layer having excellent thermal conductivity and supporting strength, and a method of manufacturing the same.

Further, the present invention provides a method of manufacturing a multilayered printed circuit board in which no additional PSR process is required because a metal, formed on the outermost layer of one side of a build-up layer, functions as a solder resist layer, and a multilayered printed circuit board manufactured using the method.

An aspect of the present invention provides a multilayered printed circuit board, including: a metal base layer including a metal layer, through-holes formed in the metal layer, an insulating film formed on a surface of the metal layer, a first circuit layer having circuit patterns, formed on one side of the metal layer, and a second circuit layer having protruding connecting pads for attaching solder balls thereto, formed on the other side of the metal layer; a build-up layer formed on the first circuit layer, the build-up layer including a plurality of insulating layers and a plurality of circuit layers; and a solder resist layer formed on an outermost layer of the build-up layer.

Here, the metal layer is composed of any one selected from among stainless steel, aluminum (Al), nickel (Ni), magnesium (Mg), zinc (Zn), tantalum (Ta), and alloys thereof.

Further, the insulating film is an insulating resin coating film or an anodizing film.

Further, the insulating resin coating film includes an epoxy resin coating film.

Further, the metal base layer functions as an embedded capacitor.

Furthermore, the multilayered printed circuit board further includes solder balls attached to the connecting pads of the second circuit layer.

Another aspect of the present invention provides a method of manufacturing a multilayered circuit board, including: forming through-holes in a metal layer and then insulating a surface of the metal layer; forming a first circuit layer including circuit patterns on one side of the insulated metal layer and forming a second circuit layer including connecting pads for attaching solder balls thereto on the other side thereof; forming a build-up layer on the first circuit layer, the build-up layer including a plurality of insulating layers and a plurality of circuit layers; and forming a solder resist layer on an outermost layer of the build-up layer.

In this case, the through-holes are formed through laser drilling or mechanical drilling.

Further, in the insulating the surface of the metal layer, the metal layer is insulated by coating the metal layer with an insulating resin or forming an anodizing film on the metal layer through an anodizing process.

Further, the method of manufacturing a multilayered printed circuit board further includes: after the forming the solder resist layer, forming openings in the solder resist layer through LDA (Laser Direct Ablation).

### BRIEF DESCRIPTION OF THE DRAWINGS

The above and other objects, features and advantages of the present invention will be more clearly understood from the following detailed description taken in conjunction with the accompanying drawings, in which:

FIGS. 1A-1E are sectional views showing a conventional process of manufacturing a coreless substrate;

FIG. 2 is a sectional view showing a multilayered printed circuit board according to an embodiment of the present invention; and

FIGS. 3A-3F are sectional views showing a process of manufacturing the multilayered printed circuit board of FIG. 2.

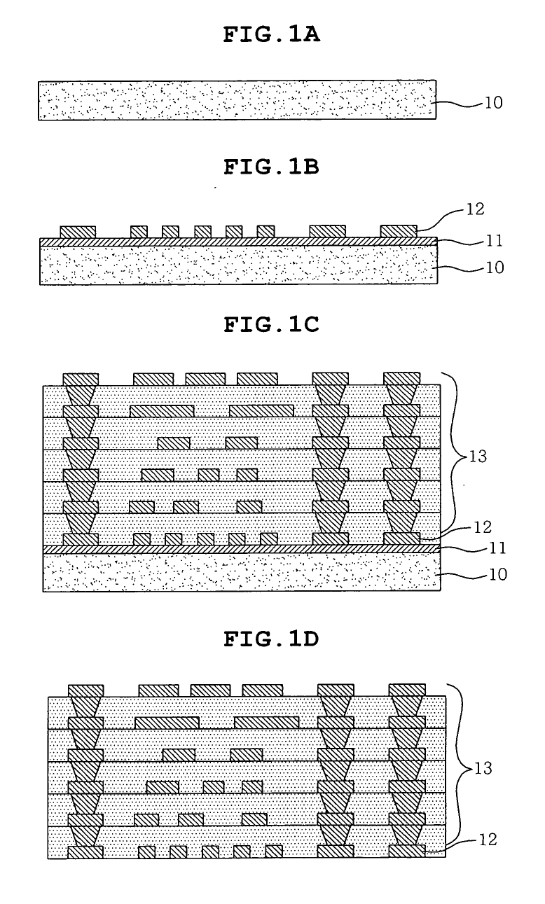

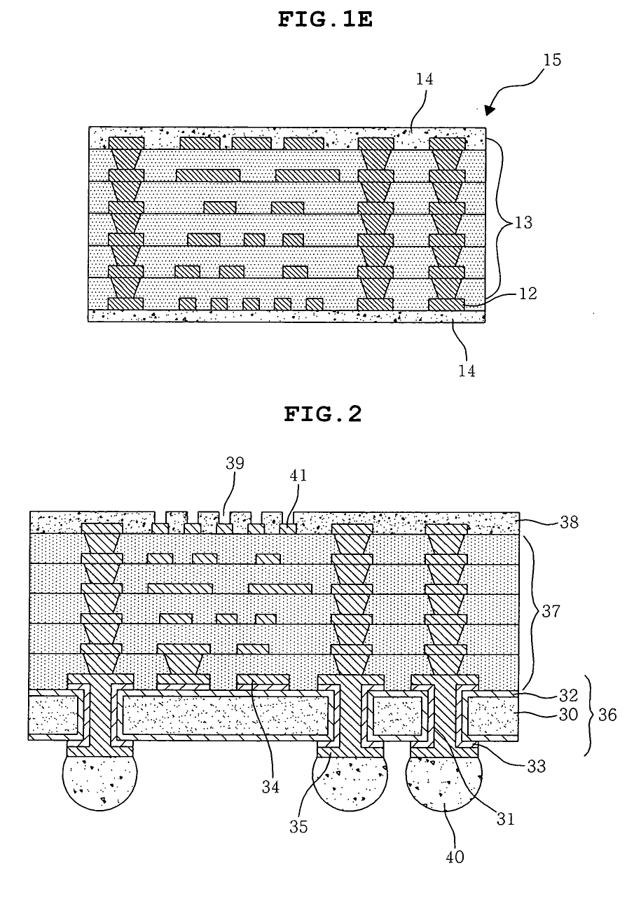

### DESCRIPTION OF THE PREFERRED EMBODIMENTS

Hereinafter, preferred embodiments of the present invention will be described in detail with reference to the attached drawings.

Reference now should be made to the drawings, in which the same reference numerals are used throughout the different drawings to designate the same or similar components.

FIG. 2 is a sectional view showing a multilayered printed circuit board according to an embodiment of the present invention.

The multilayered printed circuit board according to an embodiment of the present invention includes a metal base layer 36, a build-up layer 37, and a solder resist layer 38.

The metal base layer 36 includes a metal layer 30; through-holes 31 for interlayer connection, formed in the metal layer 30; an insulating film 32 formed on the surface of the metal layer 30; a first circuit layer including circuit patterns 34, formed on one side of the metal layer 30; and a second circuit layer including connecting pads 35 for attaching solder balls thereto, formed on the other side of the metal layer 30.

Here, the metal layer 30, which conducts a support function and a radiation function, is composed of any one selected from among stainless steel, aluminum (Al), nickel (Ni), magnesium (Mg), zinc (Zn), tantalum (Ta), and alloys thereof.

Further, the insulating film 32, which serves to electrically insulate the metal layer 30, may be an insulating resin coating film or an anodizing film.

Meanwhile, the metal base layer 36 can be used as an embedded capacitor by connecting it to an external power source. That is, the metal layer 30 formed thereon with the insulating film 32 serves as a dielectric, and the circuit layers formed on/beneath the dielectric serve as upper and lower electrodes, respectively, so that the metal base layer 36 can be used as a built-in capacitor by connecting it to an external power source.

Further, solder balls 40 may be attached to the connecting pads 35.

The build-up layer 37 includes a plurality of insulating layers and a plurality of circuit layers, and is formed on the first circuit layer.

The solder resist layer 38 is formed on the outermost layer of the build-up layer 37 to protect circuit patterns and electrically insulate them. Further, the solder resist layer 38 is provided with opening 39 to expose connecting terminals 41, formed on the outermost layer of the build-up layer 37, connected with other electronic products.

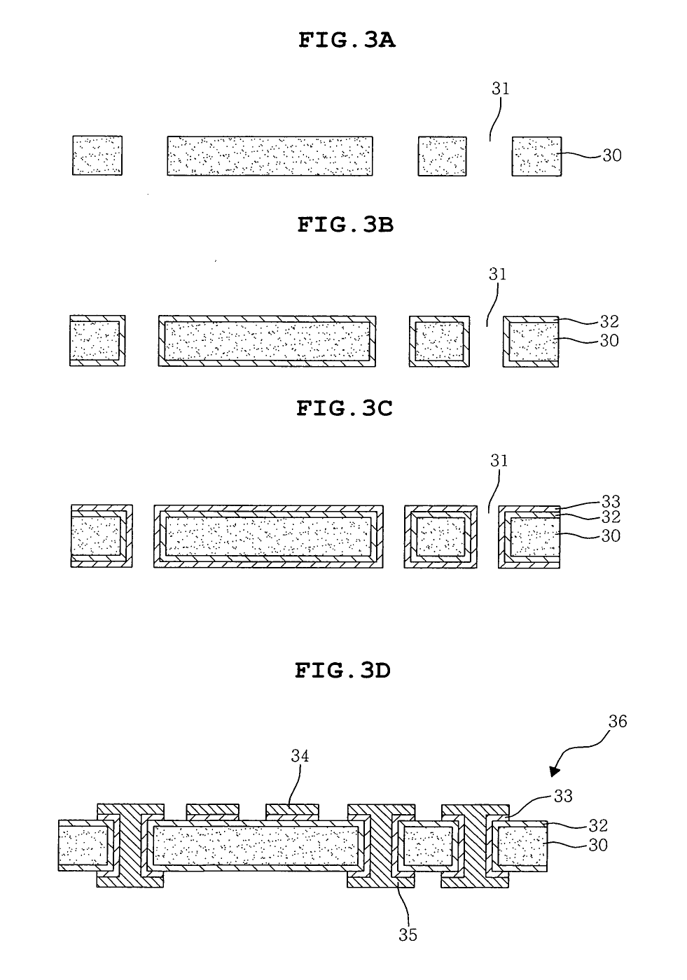

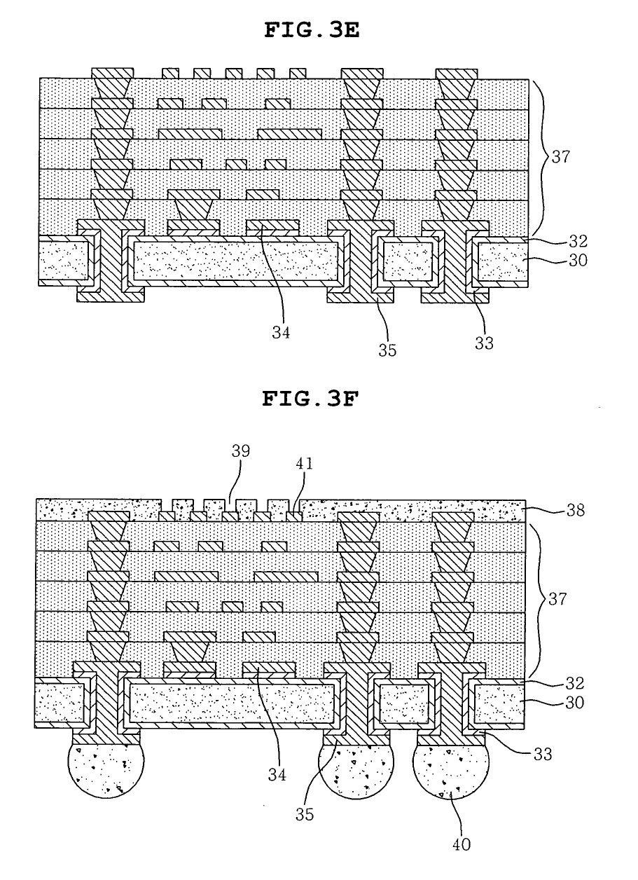

FIG. 3 is sectional views showing a process of manufacturing the multilayered printed circuit board of FIG. 2. Hereinafter, the process of manufacturing the multilayered circuit board of FIG. 2 will be described with reference to FIG. 3.

First, as shown in FIG. 3A, through-holes 31 for interlayer connection are formed in a metal layer 30.

Here, the metal layer 30 functions as a support of the multilayered printed circuit board and serves to improve the radiation efficiency of the multilayered printed circuit board. The metal layer 30 is composed of any one selected from among stainless steel, aluminum (Al), nickel (Ni), magnesium (Mg), zinc (Zn), tantalum (Ta), and alloys thereof. Since this metal layer 30 has high thermal conductivity and high strength, a coreless substrate having excellent radiation performance can be fabricated using the metal layer 30.

Further, the through-holes 31 are formed through drilling work using a CNC (computer numerical control) drill, a CO₂ laser drill, or a YAG (yttrium aluminum garnet) drill.

Subsequently, as shown in FIG. 3B, an insulating film 32 is formed over the entire surface of the metal layer 30, thus enabling a circuit layer to be formed.

Here, the insulating film 32 may be formed by coating the metal layer 30 with an insulating resin, for example, an epoxy resin, or through an anodizing process.

Specifically, in the anodizing process, the metal layer 30 is dipped into an electrolyte, such as boronic acid, phosphoric acid, sulfuric acid, chromic acid, or the like, and then the metal layer 30 is connected to an anode and the electrolyte is connected to a cathode, thus growing an oxidation layer (Al₂O₄) over the entire surface of the metal layer 30.

Subsequently, as shown in FIG. 3C, a thin seed layer 33 is formed on the insulating film 32 formed on the metal layer 30 through electroless plating. Electroless plating is a surface treatment method for imparting conductivity to the surface of nonconductive materials by depositing metal on the surface thereof through a reduction reaction. In the present invention, since electrolytic plating cannot be directly conducted on the insulated metal layer 30 by electrolysis, electroless plating is first conducted in order to impart conductivity to the insulated metal layer 30.

Subsequently, as shown in FIG. 3D, through a general circuit pattern forming method, a first circuit layer including circuit patterns 34 is formed on one side of the metal layer 30 and a second circuit layer including connecting pads 35 for attaching solder balls thereto is formed on the other side thereof, thus fabricating a metal base layer 36.

Subsequently, as shown in FIG. 3E, a build-up layer 37 including a plurality of insulating layers and a plurality of circuit layers is formed on the first circuit layer. Here, the build-up layer 37 may be formed using a general build-up method.

Here, the build-up layer 37 is interlayer-connected through the through-holes, and the first circuit layer is connected with circuit layers of the build-up layer 37 through the through-holes.

Further, the insulating layers may be formed of a commonly-used epoxy resin, a glass epoxy resin, an alumina-containing epoxy resin, or the like, but the present invention is not limited thereto. Further, the thickness of the insulating layers may be variously changed if necessary, and, as described above, the insulating layers can be thinly formed because the metal layer 30 serves as a support thereof.

Subsequently, as shown in FIG. 3F, a solder resist layer 38 is formed on the uppermost layer of the build-up layer 37, and openings 39 are formed in the solder resist layer 38 such that connecting terminals 41 formed in the uppermost layer of the build-up layer 37 protrude and are thus connected with other electronic parts. Here, these openings 39 can be formed through mechanical work, such as LDA (Laser Direct Ablation).

Meanwhile, since the metal layer 30 functions as a solder resist layer for protecting the lowermost circuit patterns, other than the portion in which the connecting pads for attaching the solder balls thereto are formed, an additional PSR process is not required.

Further, solder balls 40 for connecting a main board or electronic parts therewith may be attached to the connecting pads 35 of the second circuit layer.

Through the above processes, the multilayered printed circuit board, shown in FIG. 2, is manufactured.

As described above, the multilayered printed circuit board and method of manufacturing the same according to the present invention is advantageous in that a metal base layer supports a build-up layer after a manufacturing process as well as during the manufacturing process, thus preventing the multilayered circuit board from being bent.

Further, the multilayered printed circuit board according to the present invention is advantageous in that it has excellent radiation characteristics because it includes a metal layer having excellent conductivity.

Further, the method of manufacturing the multilayered circuit board according to the present invention is advantageous in that no additional PSR process is required because a metal layer serves to protect circuit patterns formed on the outermost layer of a build-up layer and to electrically insulate them.

Furthermore, the present invention provides a multilayered printed circuit board including a built-in capacitor because a metal base layer functions as a capacitor.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A multilayered printed circuit board, comprising:
a metal base layer including a metal layer, through-holes formed in the metal layer, an insulating film formed on a surface of the metal layer, a first circuit layer having circuit patterns, formed on one side of the metal layer, and a second circuit layer having protruding connecting pads for attaching solder balls thereto, formed on the other side of the metal layer;
a build-up layer formed on the first circuit layer, the build-up layer including a plurality of insulating layers and a plurality of circuit layers; and
a solder resist layer formed on an outermost layer of the build-up layer.

2. The multilayered printed circuit board according to claim 1, wherein the metal layer includes any one selected from among stainless steel, aluminum (Al), nickel (Ni), magnesium (Mg), zinc (Zn), tantalum (Ta), and alloys thereof.

3. The multilayered printed circuit board according to claim 1, wherein the insulating film includes an insulating resin coating film or an anodizing film.

4. The multilayered printed circuit board according to claim 3, wherein the insulating resin coating film includes an epoxy resin coating film.

5. The multilayered printed circuit board according to claim 1, wherein the metal base layer functions as an embedded capacitor.

6. The multilayered printed circuit board according to claim 1, further comprising:
solder balls attached to the connecting pads of the second circuit layer.

7. A method of manufacturing a multilayered circuit board, comprising:
forming through-holes in a metal layer and then insulating a surface of the metal layer;
forming a first circuit layer including circuit patterns on one side of the insulated metal layer and forming a second circuit layer including connecting pads for attaching solder balls thereto on the other side thereof,
forming a build-up layer on the first circuit layer, the build-up layer including a plurality of insulating layers and a plurality of circuit layers; and
forming a solder resist layer on an outermost layer of the build-up layer.

8. The method of manufacturing a multilayered printed circuit board according to claim 7, wherein the through-holes are formed through laser drilling or mechanical drilling.

9. The method of manufacturing a multilayered printed circuit board according to claim 7, wherein, in the insulating the surface of the metal layer, the metal layer is insulated by coating the metal layer with an insulating resin or forming an anodizing film on the metal layer through an anodizing process.

10. The method of manufacturing a multilayered printed circuit board according to claim 7, further comprising: after the forming the solder resist layer, forming openings in the solder resist layer through LDA (Laser Direct Ablation).
